(19) United States
(12) Patent Application Publication
(10) Pub. No.: US 2009/0301763 A1
(43) Pub. Date: Dec. 10, 2009

(54) INK, METHOD OF FORMING ELECTRICAL TRACES USING THE SAME AND CIRCUIT BOARD

(75) Inventors: CHENG-HSIEN LIN, Tayuan (TW); RUI ZHANG, Shenzhen City (CN); YAO-WEN BAI, Shenzhen City (CN)

Correspondence Address: PCE INDUSTRY, INC.;ATT. Steven Reiss, 288 SOUTH MAYO AVENUE, CITY OF INDUSTRY, CA, 91789, US

(73) Assignees: FUKUI PRECISION COMPONENT (SHENZHEN) CO., LTD., Shenzhen City (CN); FOXCONN ADVANCED TECHNOLOGY INC., Tayuan (TW)

(21) Appl. No.: 12/331,481

(22) Filed: Dec. 10, 2008

(30) Foreign Application Priority Data
Jun. 5, 2008 (CN) 200810302036.X

(51) Int. Cl. B05D 3/06; C09D 11/00; H05K 1/00

(52) U.S. Cl. 174/250; 427/558; 106/31.92

(57) ABSTRACT

An exemplary ink for forming electrical traces includes a plurality of noble-metal-coated diacetylene vesicles formed by combining a noble-metal-ions-containing aqueous solution with diacetylenic monomers each including a hydrophilic group and a lipophilic group. The noble metal ions are attracted to an external surface of each of the diacetylene vesicles.

### CROSS-REFERENCE TO RELATED APPLICATIONS

This application relates to commonly-assigned copending applications Ser. No. 12/235,994, entitled “METHOD OF FORMING CIRCUITS ON CIRCUIT BOARD”, and U.S. Ser. No. 12/253,869, entitled “PRINTED CIRCUIT BOARD AND METHOD FOR MANUFACTURING SAME”, Ser. No. 12/327,621, entitled “INK AND METHOD OF FORMING ELECTRICAL TRACES USING THE SAME”, and Ser. No. ______ entitled “METHOD OF FORMING ELECTRICAL TRACES ON SUBSTRATE” (attorney docket number US 22201). Disclosures of the above-identified applications are incorporated herein by reference.

### BACKGROUND

1. Technical Field

The present disclosure relates generally to an ink, and particularly, to an ink containing diacetylene vesicles, a method of forming electrical traces using the ink and a circuit board manufactured by the method.

2. Description of Related Art

A method for forming circuits (or electrical traces) on a substrate in printed circuit boards and semiconductor chips using ink jet printing is becoming more and more popular. Ink jet printing is a non-impact dot-matrix printing process in which droplets of ink are jetted from a small aperture directly to a specified area of a medium to create an image thereon.

A typical ink jet printing method for manufacturing circuits is disclosed, in which an ink containing nano-scale metal particles and a disperser is applied by an ink jet printer onto a surface of a substrate to form a nano-scale metal particles pattern. The nano-scale metal particles pattern is then heat-treated (such as sintered) at a temperature of about 200 to 300 degrees Celsius. In such a manner, the disperser covering the nano-scale metal particles is removed, and then the nano-scale metal particles are meanwhile molten to form a continuous electrical trace with good conductivity. However, in the heat treatment process, the high temperature (e.g. 200 to 300 degrees Celsius.) can soften and melt the substrate due to a poor heat-resistant of the substrate, thereby, distorting the substrate. Therefore, the ink containing nano-scale metal particles is not suitable for ink jet circuits printing process.

What is needed, therefore, is an ink, a method of forming electrical traces by use of the ink and a circuit board which can overcome the above-described problems.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the present embodiments. Moreover, in the drawings, like reference numerals designate corresponding parts throughout the several views.

FIG. 1 is a flowchart of a method for forming electrical traces on a substrate, according to an exemplary embodiment.

FIG. 2 to FIG. 5 are schematic, cross-sectional views showing each step of the method illustrated in FIG. 1.

### DETAILED DESCRIPTION OF THE EMBODIMENTS

Reference will now be made to the drawings to describe an exemplary embodiment of an ink and the method of forming electrical traces using the ink in detail.

An exemplary embodiment of a ink suitable for forming electrical traces generally includes a noble-metal-ion-containing aqueous carrier medium and diacetylenic monomers dispersed in the aqueous carrier medium. The noble-metal-ions-containing aqueous solution combined with the diacetylenic monomers forms a plurality of noble-metal-coated diacetylene vesicles.

The noble-metal-ions-containing aqueous solution includes an aqueous carrier medium and a number of noble metal ions uniformly dissolved in the aqueous carrier medium.

Optionally, the aqueous carrier medium can further include water or a mixture of water and at least one water soluble organic solvent. For example, water-soluble organic solvents may be selected from the group consisting of (1) alcohols, such as methyl alcohol, ethyl alcohol, n-propyl alcohol, iso-propyl alcohol, n-butyl alcohol, sec-butyl alcohol, t-butyl alcohol, iso-butyl alcohol, furfuryl alcohol, and tetrahydrofurfuryl alcohol; (2) ketones or ketoalcohols such as acetone, methyl ethyl ketone and diacetone alcohol; (3) ethers, such as tetrahydrofuran and dioxane; (4) esters, such as ethyl lactate; (5) polyhydric alcohols, such as ethylene glycol, diethylene glycol, triethylene glycol, propylene glycol, tetraethylene glycol, polyethylene glycol, glycerol, 2-methyl-2,4-pentanediol 1,2,6-hexanetriol and thiodiglycol; (6) lower alkyl mono- or di-ethers derived from alkylene glycols, such as ethylene glycol mono-methyl (or -ethyl) ether, diethylene glycol mono-methyl (or -ethyl) ether, propylene glycol mono-methyl (or -ethyl) ether, triethylene glycol mono-methyl (or -ethyl) ether and diethylene glycol di-methyl (or -ethyl) ether; (7) nitrogen containing cyclic compounds, such as pyrrolidone, N-methyl-2-pyrrolidone, and 1,3-dimethyl-2-imidazolidinone; and (8) sulfur-containing compounds such as dimethyl sulfoxide and tetramethylene sulfone.

The noble metal ions can be selected from the group consisting of silver ions, gold ions, and platinum ions.

Each of the diacetylenic monomers includes a hydrophilic group, and a lipophilic group. In detail, each diacetylenic monomer is represented by following molecular formula:

MC≡C—C≡CN,

wherein M represents a hydrophilic group, N represents a lipophilic group. It is noted that an end of molecular of the diacetylenic monomers is hydrophilic, and another end thereof is lipophilic. The diacetylenic monomers can undergo an interpolymerization reaction with each other to form a polymer (e.g. chain polymer) in a catalysis condition (irradiation).

When a concentration of the diacetylenic monomers in the ink is higher than Critical Micelle Concentration (CMC) thereof, the diacetylenic monomers will get together to form a plurality of diacetylene vesicles. The CMC is an inherent physical property of the diacetylenic monomers corresponding to a surface activity thereof, and is different in different diacetylenic monomers. In the present embodiment, the concentration of the diacetylenic monomers is in a range from 10⁻⁷ to 10⁻¹ mol/L, and the diacetylenic monomers forms the diacetylene vesicles.

In formation process of the diacetylene vesicles, a portion of the noble metal ions is received in each of the diacetylene vesicles, and another portion thereof attract to an external surface of each of the diacetylene vesicles. Thereby, the diacetylene vesicles and the noble metal ions coated on and in each diacetylene vesicle form a plurality of noble-metal-coated diacetylene vesicles.

A preparation of the ink is clearly explained below by an example. An ethanol solution containing 1.0 ml, 1.5×10⁻¹ mol/L, diacetylene monocarboxylic acid (e.g., 10,12-pentacosadiynoic acid, CH₃(CH₂)₁₁C≡C—C≡C(CH₂)₈CO₂H) is ultrasonically treated for 5 minutes, and then is poured into an aqueous solution thereby obtaining a mixture solution. After that 6.0 ml, 1.0×10⁻² mol/L, AgNO₃ aqueous solution is also added into above mixture solution. Finally, the mixture solution is treated using ultrasonic waves for 60 minutes to produce diacetylene vesicles in the mixture solution.

Under irradiation of irradiation ray such as ultraviolet ray, an interpolymerization reaction between the diacetylene monomes occurs, thereby generating and releasing free radicals which act as free electrons by breaking triple carbon-to-carbon bond in the diacetylenic monomers. The noble metal ions (Ag¹) gain the free radicals generated from the interpolymerization reaction, and are reduced into corresponding noble metal particles (Ag).

Additionally, to improve a bonding strength between the ink and a substrate, a surface-active agent, a viscosity modifier, a binder, a humectant or mixtures thereof can be selectively added into the ink to adjust viscosity, surface tension, and stability of the ink. The surface-active agent can be anionic, cationic or non-ionic surface-active agent. The binder material can be polyurethane, polyvinyl alcohol or macromolecule polymer. To avoid deterioration of the ink, it is better to preserve the ink in a dark environment.

Compared with the nano-scale metal particles, the noble metal ions in the ink have an excellent dispersive ability, which can efficiently prevent aggregation of the nano-scale metal particles. Therefore, the noble metal ions are uniformly dissolved for achieving the electrical traces with uniform thickness and width.

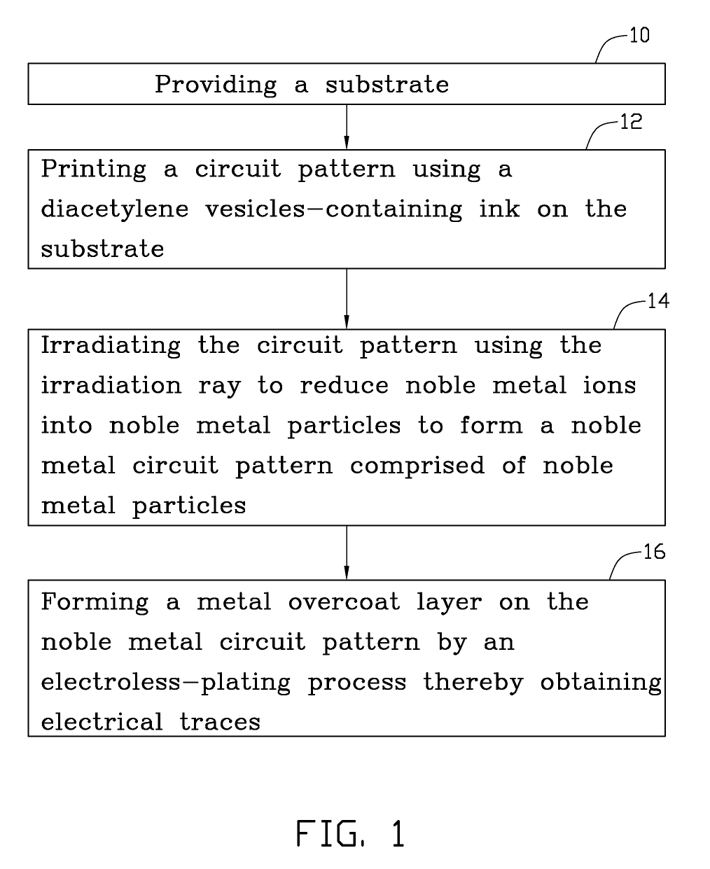

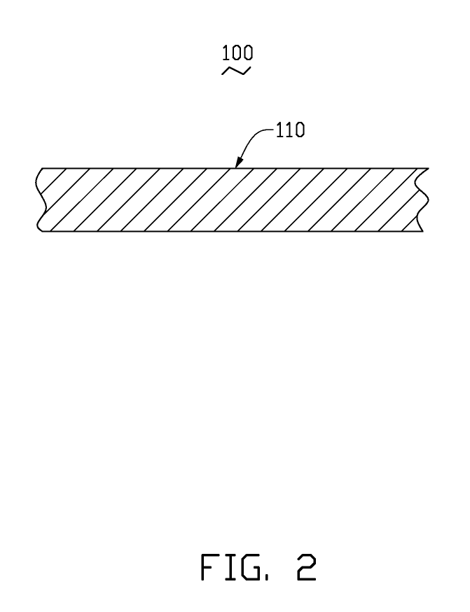

Referring to FIG. 1, an exemplary embodiment of a method of forming electrical traces on a substrate using the ink is illustrated. The method will be described in detail with reference to FIG. 2 to FIG. 5.

In step 10, referring to FIG. 2, a substrate 100 is provided. The substrate 100 is comprised of a material suitable for making printed circuit board, such as polyimide (PI), polyethylene terephthalate (PET), polyarylene ether nitrile (PEN), etc. The substrate 100 has a surface 110. To improve an bonding force between the circuit pattern 200 and the surface 110 of the substrate 100, the surface 110 can be processed using a surface treating processes, e.g., a cleaning process, a micro-etching process, to remove pollutants, oil, grease, or other contaminates from the surface 110 of the substrate 100.

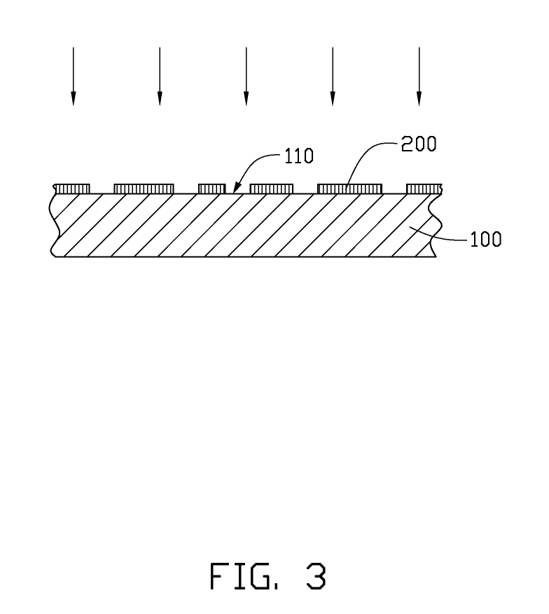

In step 12, referring to FIG. 3, a circuit pattern 200 made of the diacetylene vesicles-containing ink is formed on the substrate 100. The circuit pattern 200 is formed on the surface 110 using an ink jet printing method. In an ink jet printing process, an ink jet printer is used to form the circuit pattern 200 using the ink of the present embodiment, which includes the noble-metal-coated diacetylene vesicles, i.e. the diacetylene vesicles together with noble metal ions attracted to an external surface thereon and received therein. In the process of forming the circuit pattern 200, a nozzle of the ink jet printer is disposed above the surface 110, and the ink is ejected from the nozzle and deposited on the surface 110 to form a desired pattern, i.e., the circuit pattern 200. The circuit pattern 200 is formed by the ink. This is, the circuit pattern 200 is brought into substantial coincidence with a trace formed by the ink.

However, the noble-metal-coated diacetylene vesicles only stably exist in the solution. Therefore, drying the ink deposited on the surface 110 by heating or natural drying, correspondingly liquid solvent in the ink (such as aqueous carrier medium) is dried and the dried noble-metal-coated diacetylene vesicles remain on the surface 110 and crack. In other words, the diacetylenic monomers crack and the noble metal ions distribute along the trace same to the circuit pattern 200. As mentioned above, the noble metal ions are uniformly distributed on the surface 110. Thus, the circuit pattern 200 has a uniform thickness and width on the surface 110.

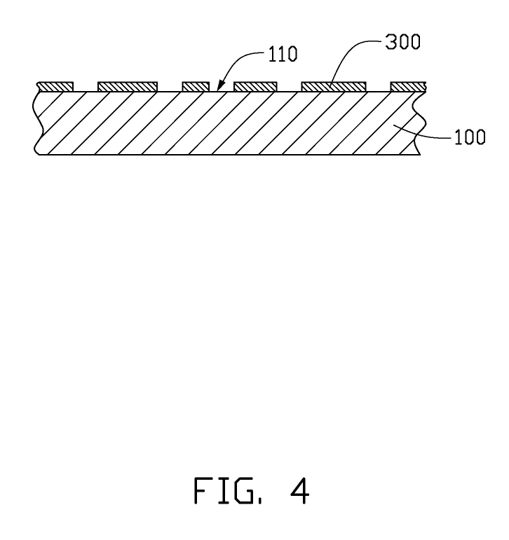

Continuing to step 14, referring to FIGS. 3 and 4, an irradiation ray irradiates the circuit pattern 200 for reducing the noble metal ions in the ink into noble metal particles, thus the circuit pattern 200 is converted or transformed into a noble metal particle circuit pattern 300 comprised of the noble metal particles. The irradiation ray can be chosen from any high energy ray such as an ultraviolet ray, laser, and γ radiation. The irradiating time is generally from about 1 minute to about 12 minutes to easily break the triple carbon-to-carbon for creating reaction and shorten a manufacturing circle time of the noble metal particle circuit pattern 300. In addition, the types of irradiation ray and the irradiating time can vary according to practical requirements.

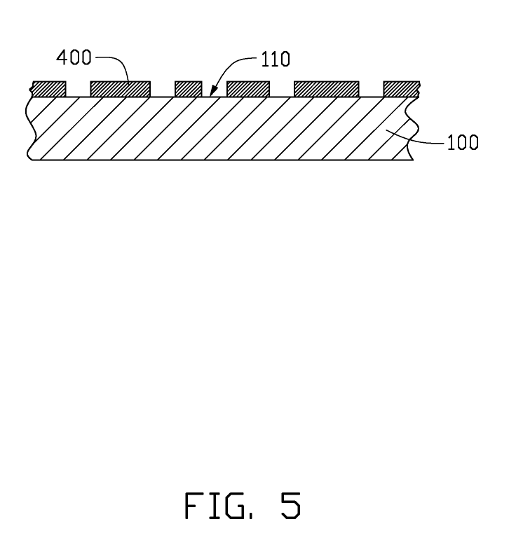

In step 16, as shown in FIG. 5, a metal overcoat layer is plated on the noble metal particle circuit pattern 300 to form a number of electrical traces 400 using an electroless-plating method. Generally, the noble metal particle circuit pattern 300 comprised of a number of noble metal particles has a low electrical conductivity due to its incompact structure. Thus, a metal overcoat layer is further plated on the noble metal particle circuit pattern 300 to improve an electrical conductivity of the electrical traces 400.

In the plating process for the electrical traces 400, each of the noble metal particles in the noble metal particle circuit pattern 300 is a reaction center, and the metal encapsulates each of the noble metal particles. Spaces between adjacent noble metal particles are entirely filled with the metal. Therefore, the noble metal particles of the noble metal particle circuit pattern 300 are electrically connected to each other by the metal, thereby improving the electrical conductivity of the electrical traces 400.

In the present embodiment, the metal overcoat layer is a copper overcoat layer and is formed by an electroless-plating method on the noble metal particle circuit pattern 300. In detail, the noble metal particle circuit pattern 300 is dipped into an electroless-plating solution comprising a plurality of copper ions at 50 degrees Celsius for 2 minutes. Copper particles are deposited in the spaces between adjacent noble metal particles thereby forming the electrical traces 400, in which the noble metal particles are electrically connected to each with the copper particles.

Moreover, the electroless-plating solution may further include other materials, such as a copper compound, a reducing agent, a complex agent and a PH modifier. The copper compound may be copper sulfate, copper chloride and other copper ion-containing compounds. The reducing agent may be dimethylaminoborane, borohydride, glyoxylic acid, dihydroxy acetic acid, formaldehyde, and hypophosphite. The complex agent may be ethylene diamine tetraacetic acid. The PH modifier may be sodium hydroxide, sodium carbonate, or potassium hydroxide. The electroless-plating solution can also include a stabilizing agent, a surface-active agent and a brightening agent therein for meeting practical electroless-plating requirement.

The surface 110 of the substrate 100 forming the electrical traces 400 is used to manufacture electrical device, for example, printed circuit boards and semiconductor application. The method of the present embodiment provides a combination of chemical reaction and plating methods, instead of a high temperature sintering to connect nano-scale metal particles with each other. Therefore, the method improves continuity and electro-conductivity of electrical traces 400, and avoids the difficulty of controlling temperature during a sintering process.

With Reference to FIG. 5, a circuit board is finished by an illustrated method. The circuit board includes a substrate 100, electrical traces 400 formed on the substrate 100. The electrical traces 400 include a noble metal particles layer (not shown) in contact with the substrate 100 and a metal overcoat layer 400 formed on the noble metal particle layer. The noble metal particles layer includes polymer formed by polymerizing a plurality of diacetylenic monomers, and a plurality of noble metal ions therein. The polymer is respected by following molecular formula:

M-C₄H₂—Nₙ

Wherein M represents a hydrophilic group, and N represents a lipophilic group. In the illustrated embodiment, the noble metal ions are selected from the group consisting of silver ions, gold ions, palladium ions and platinum ions. The metal overcoat layer 400 is selected from the group consisting of copper overcoat layer and nickel overcoat layer.

While certain embodiments have been described and exemplified above, various other embodiments from the foregoing disclosure will be apparent to those skilled in the art. The present disclosure is not limited to the particular embodiments described and exemplified but is capable of considerable variation and modification without departure from the scope of the appended claims.

What is claimed is:

1. An ink for forming electrical traces, comprising:
a plurality of noble-metal-coated diacetylene vesicles formed by combining a noble-metal-ions-containing aqueous solution with diacetylenic monomers each including a hydrophilic group, and a lipophilic group, wherein the noble metal ions are attracted to an external surface of each of the diacetylene vesicles.

2. The ink as claimed in claim 1, wherein the noble metal ions are selected from the group consisting of silver ions, gold ions, and platinum ions.

3. The ink as claimed in claim 1, wherein a concentration of the diacetylenic monomers is in a range from 10⁻⁷ to 10⁻¹ mol/L.

4. The ink as claimed in claim 1, wherein the hydrophilic group is selected from the group consisting of carboxylic group, sulfonic group and amino group, and the lipophilic group is alkyl group.

5. The ink as claimed in claim 1, further comprising a binder selected from the group consisting of polyurethane, polyvinyl alcohol and macromolecule polymer, and a surface-active agent selected from the group consisting of anionic, cationic and non-ionic surface-active agent.

6. A method for forming electrical traces on a substrate comprising:
printing a circuit pattern using a diacetylene vesicles-containing ink on the substrate, the ink comprising:
a noble-metal-ion-containing aqueous carrier medium;
diacetylenic monomers dispersed in the aqueous carrier medium, the diacetylenic monomers each being represented by following molecular formula:
MC≡C—C≡CN,
wherein M represents a hydrophilic group, and N represents a lipophilic group, wherein the diacetylenic monomers form a plurality of diacetylene vesicles; and
the noble metal ions are attracted to an external surface of each of the diacetylene vesicles;
irradiating the circuit pattern using the irradiation ray to reduce noble metal ions into noble metal particles to form a noble metal circuit pattern comprised of noble metal particles; and
forming a metal overcoat layer on the noble metal circuit pattern by an electroless-plating process thereby obtaining electrical traces.

7. The method as claimed in claim 6, wherein a concentration of the diacetylenic monomers is in a range from 10⁻⁷ to 10⁻¹ mol/L.

8. The method as claimed in claim 6, wherein the metal overcoat layer is comprised of copper.

9. The method as claimed in claim 6, wherein the electroless-plating solution used in the electtroless-plating process contains a material selected from the group consisting of dimethylaminoborane, borohydride, glyoxylic acid, dihydroxy acetic acid, formaldehyde, and hypophosphite.

10. The method as claimed in claim 6, wherein the irradiation ray is an ultraviolet ray.

11. The method as claimed in claim 6, wherein the circuit pattern is irradiated for about 1 minute to about 20 minutes.

12. The method as claimed in claim 6, further comprising drying the circuit pattern before forming a noble metal circuit pattern.

13. A circuit board comprising:
a substrate;
electrical traces formed on the substrate, the electrical traces including a noble metal particles layer in contact with the substrate; and
a metal overcoat layer formed on the noble metal particle layer.

14. The circuit board as claimed in claim 13, wherein the noble metal ions are selected from the group consisting of silver ions, gold ions and platinum ions.

15. The circuit board as claimed in claim 13, wherein a concentration of the diacetylenic monomer is in a range from 10⁻⁷ to 10⁻¹ mol/L.

16. The circuit board as claimed in claim 13, wherein the metal overcoat layer is selected from the group consisting of copper overcoat layer and nickel overcoat layer.
